(19) United States
(12) Patent Application Publication
(10) Pub. No.: US 2002/0025619 A1
(43) Pub. Date: Feb. 28, 2002

(54) Multilayer film structure with high tunneling magneto-resistance ratio and the manufacturing method of the same

(76) Inventors: Chi-Kuen Lo, Hsinchu (TW); Chia-Hwo Ho, Kaohsiung (TW); Minn-Tsong Lin, Taipei (TW); Yeong-Der Yao, Taipei (TW); Der-Ray Huang, Hsinchu City (TW)

Correspondence Address: W. Wayne Liauh, Ph.D., J.D., Law Office of Liauh and Associates, 4224 Waialae Ave., Ste 5-388, Honolulu, HI, 96816, US

(21) Appl. No.: 09/745,154

(22) Filed: Dec. 19, 2000

(30) Foreign Application Priority Data
Aug. 31, 2000 (TW) 89117734

(51) Int. Cl. H01L 21/8238; B32B 7/02

(52) U.S. Cl. 438/212; 438/209; 428/212

(57) ABSTRACT

This specification disclosed a multilayer film structure of a tunneling magneto-resistor and the manufacturing of the same, the structure being able to increase the tunneling magneto-resistance (TMR) ratio and to decrease the difficulty in manufacturing. The multilayer film structure disclosed herein forms, in a three-layer film structure composed of two layers of ferromagnetic films and an insulating layer provided in between, a layer of moderately thick ferromagnetic metal insertion between one of the ferromagnetic film and the insulating layer. Through the insertion the tunneling magneto-resistance ratio can be greatly increased and the thickness of the insulating layer is increased to the range where the manufacturing difficulty is lowered.

### BACKGROUND OF THE INVENTION

1. Field of Invention

The present invention relates to a multilayer structure of a tunneling magneto-resistor and the manufacturing method of the same. More particularly, it relates to a tunneling magneto-resistive (TMR) material with high magneto-resistance ratio that applies to magneto-electronic devices such as micro magnetic field sensors, high density magnetic recording pickup heads, decoders, nonvolatile magneto-resistive random access memory (MRAM), etc.

2. Related Art

The giant magneto-resistive (GMR) material has been widely used in magnetoelectronic devices such as micro magnetic field sensors, high density magnetic recording pickup heads, decoders, and nonvolatile magneto-resistive random access memory (MRAM) after a decade since its discovery and will play an important role in future electronics technologies. The tunneling magneto-resistive (TMR) material has even higher magneto-resistance ratio and intrinsic resistance, which make the TMR material more practical than the GMR material. The basic structure of the TMR material is FM₁/I/FM₂ three film layers, wherein FM₁ and FM₂ are ferromagnetic films made of the same or different materials and I is an insulating layer. Since electrons need to tunnel from FM₁ to FM₂ (or the other way around), the thickness of the insulating layer I has to be less than tens of angstrom (Å). The insulating layer is usually made of aluminum oxide because it does not bring in big change to the energy band structure of the ferromagnetic layers and its spin scattering is small. The junction between the ferromagnetic film and the insulating layer cannot have any pinhole; otherwise it will cause a short circuit between the ferromagnetic films. The two ferromagnetic films can be made of materials with the same or different coercive forces and have the insulating layer in between. There is a relation between the tunneling magneto-resistance and the magnetization strength. Therefore, a better tunneling magneto-resistance ratio can be obtained by adjusting the type or structure of the ferromagnetic material used.

Generally speaking, the optimal thickness of the insulating layer is quite thin in a sandwich TMR system. For example, in the Co/Al₂O₃/NiFe TMR system proposed in J. S. Moodera, E. F. Gallagher, K. Robinson, and J. Nowak, Appl. Phys. Lett. 70, 3050 (1997), the thickness of the insulating layer (Al₂O₃ layer) is only about 5 Å to 16 Å. The TMR ratio can reach 16.5% at the room temperature. It is proposed in R. Jansen, and J. S. Moodera, J. Appl., 83, 6682 (1998) that one can add in a small amount of magnetic particles (<2 Å) between the junctions of the insulating layer and the ferromagnetic layers at the optimal insulating layer thickness so as to lower the tunneling magneto-resistance ratio. Co is added into the junctions in the TMR system with double barriers in F. Montaigne, J. Nassar, A. Vaures, F. Nguyen Van Dau, F. Petroff, A. Schuhl, and A. Fert, Appl. Phys. Lett. 73, 2829 (1998), the TMR ratio also decreases. Therefore, one knows that when a small amount (<2 Å) of magnetic insertion at the junctions between the insulating layer and the ferromagnetic layers, the TMR ratio usually goes down.

Although the above-mentioned Co/Al₂O₃/NiFe structure can reach a high TMR ratio, the thickness of the Al₂O₃ insulating layer lies between 5 Å and 16 Å. The thinner the insulating layer is the more difficult the manufacturing process is. On the other hand, it is easier to fabricate an insulating layer of 20 Å thick, however, the TMR ratio approaches 0 at this thickness of the insulating layer.

In order to reduce the difficulty in fabrication and to increase the yield of the TMR material, it is highly desirable to increase the thickness of the insulating layer without reducing the TMR ratio too much. The multilayer film structure with a high TMR ratio and the manufacturing method thereof disclosed herein can satisfy such a need.

### SUMMARY OF THE INVENTION

It is an object of the invention to develop a multilayer film structure with a high tunneling magneto-resistance (TMR) ratio and the manufacturing method of the same that can increase the TMR ratio while at the same time lower the manufacturing difficulty.

Pursuant to the above object, the present invention adds into the junction between an insulating layer and a ferromagnetic film layer a moderately thick insertion so as to greatly increase the TMR ratio and to allow a thicker insulating layer.

To achieve the above object, the present invention provides a multilayer film structure with a high TMR ratio. The multilayer film structure comprises two ferromagnetic film layers, an insulating layer provided between the two ferromagnetic film layers and a ferromagnetic metal insertion between one of the ferromagnetic film layers and the insulating layer. The thickness of the ferromagnetic metal insertion is preferably between 8 Å and 20 Å.

With the ferromagnetic metal insertion, the TMR ratio will be larger than that without an insertion.

In the disclosed high TMR multilayer film structure, the two ferromagnetic films can be made of ferromagnetic materials of the same or different coercive forces. They can be an alloy selected from the group comprising Fe, Co, Ni and their combinations. The insertion material can also be a ferromagnetic alloy selected from the group comprising Fe, Co, Ni and their combinations. But the insertion material has to be different from that of the adjacent ferromagnetic film. The thickness of the insertion is preferably between 8 Å and 20 Å. Furthermore, the insulating layer material can be Al₂O₃ so that the TMR multilayer film structure can still have a high TMR ratio even when the thickness is more than 20 Å.

To achieve the above object, the present invention also provides a manufacturing method of the high TMR ratio multilayer structure, which comprises the steps of: (a) forming a first ferromagnetic film on a substrate; (b) forming an insulating layer on the first ferromagnetic film; (c) forming a ferromagnetic metal insertion with a thickness between 5 Å and 26 Å on the insulating layer; and (d) forming a second ferromagnetic film on the insertion; wherein the second ferromagnetic film and the first ferromagnetic film are made of ferromagnetic materials with the same or different coercive forces and they are made of different ferromagnetic materials from the insertion.

Other features and advantages of the present invention will be apparent from the following detailed description, which proceeds with reference to the accompanying drawings.

### BRIEF DESCRIPTION OF THE DRAWINGS

FIG. 1 is a schematic view of a TMR multilayer film structure Glass/Co(100 Å)/Al₂O₃(23 Å)/Co(t Å)/NiFe(100 Å) in a first embodiment of the invention;

FIG. 2 depicts the relation between the insertion thickness and the TMR ratio in the first embodiment;

FIG. 3 is a schematic view of a TMR multilayer film structure Glass/Co(100 Å)/Al₂O₃(23 Å)/Co(t Å)/NiFe(100 Å) in a second embodiment of the invention; and

FIG. 4 shows a magneto-resistance curve of the multilayer film structure in the second embodiment.

In the various drawings, the same references relate to the same elements.

### DETAILED DESCRIPTION OF THE INVENTION

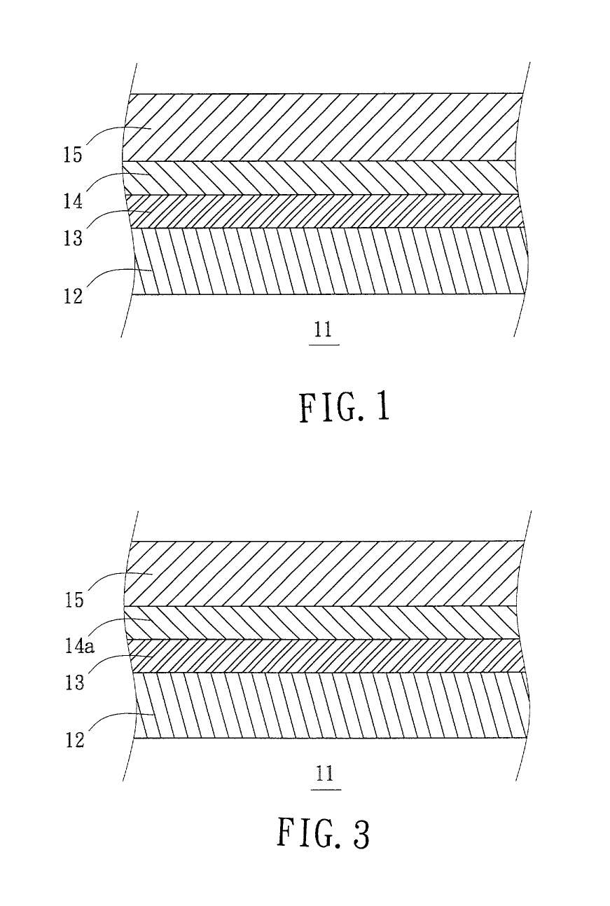

FIG. 1 is a schematic view of a TMR multilayer film structure in a first preferred embodiment of the invention. The structure includes a substrate 11, which can be a non-conductive corning glass (No. 7059), semiconducting substrates such as Si, Ge, etc. The root-mean-square (rms) surface roughness of the corning glass is about 20 Å. The substrate 11 is formed with a layer of Co metal film 12 of 100 Å thick thereon. The Co metal film 12 is formed with an aluminum oxide (Al₂O₃) insulating layer 13 of 23 Å thick thereon. The aluminum oxide (Al₂O₃) insulating layer 13 is then formed with a Co insertion 14, whose thickness is preferably between 8 Å and 20 Å. The Co insertion 14 is formed with a iron-nickel alloy film 15 composed of 80% nickel and 20% iron. The TMR multilayer film structure can be expressed by Glass/Co(100 Å)/Al₂O₃(23 Å)/Co(t Å)/NiFe(100 Å), where t=8 Å˜20 Å. The tunneling junction of the Co metal film 12, the aluminum oxide insulating layer 13 and the Co insertion 14/iron-nickel alloy film 15 is 1 mm×1 mm.

The manufacturing method of the multilayer film structure comprises the steps of: coating the Co metal film 12 of 100 Å thick on the substrate 11; coating an aluminum oxide insulating layer 13 of 23 Å thick on the Co metal film 12; coating a Co insertion 14 of 8 Å to 20 Å thick on the aluminum oxide insulating layer 13; and coating a iron-nickel alloy film 15 of 100 Å thick on the Co insertion 14. Vacuum sputtering can be applied to the coating of the Co metal film 12 on the substrate 11 and the Co insertion 14 on the aluminum oxide insulating layer 13; wherein a DC magnetic sputtering gun is employed in argon at 2 mtorr. The step of coating the aluminum oxide insulating layer 13 on the Co metal film 12 can include the following two steps: (1) Use the off-axis magnetic sputtering method to coat an aluminum film with argon pressure of 2 mtorr; (2) Provide oxygen pressure of 0.2 torr for 40 seconds of natural oxidation and perform an RF growth discharge oxidation at 5×10⁻² torr in a mixture of argon and oxygen (pressure ratio 1:1 and flux ratio 16:9) at the power of 100W for 1 minute. The tunneling junction thus made has about 25 Å of potential barrier width and 1 eV to 3 eV of potential barrier height.

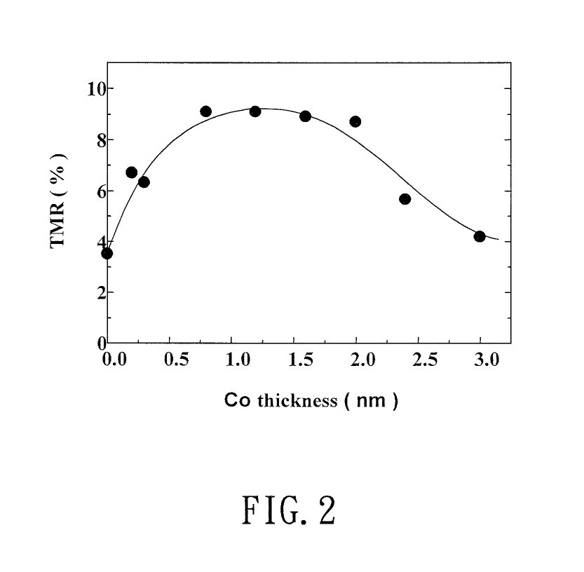

FIG. 2 depicts the relation between the Co insertion thickness t and the TMR ratio of the TMR multilayer film structure in the first embodiment. When the Co insertion 14 thickness t=8 Å˜20 Å, the TMR ratio under the room temperature can reach 8%˜9%. When the Co insertion 14 thickness t=0 (i.e. the conventional tunneling magnetic resistor), the TMR ratio under the room temperature is only 3.5%. The TMR ratio is rising as t is increased to 0.8 Å as shown in FIG. 2. Therefore, after inserting the Co insertion 14 the TMR ratio can increase by a factor of more than 2. Moreover, it is easier to fabricate an aluminum oxide insulating layer 13 with a thickness of 23 Å.

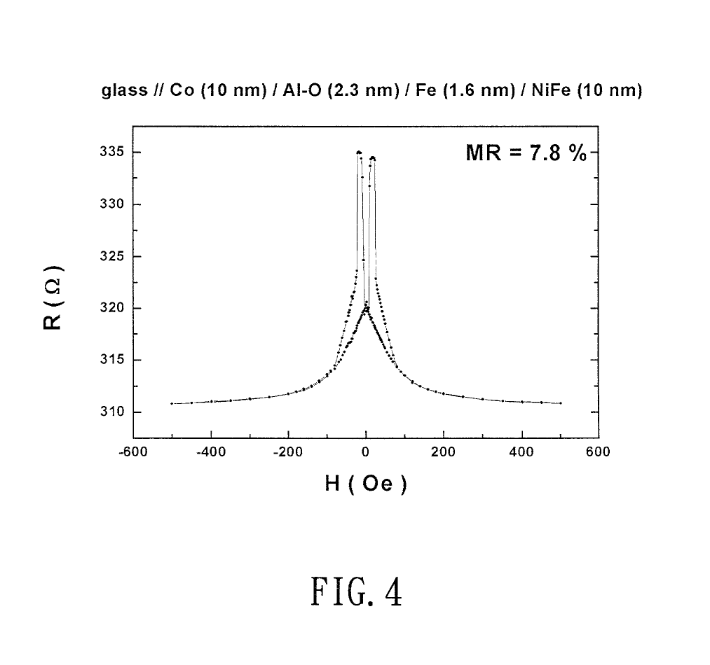

FIG. 3 is a schematic view of a TMR multilayer film structure in a second embodiment of the invention. The structure comprises a glass substrate 11, a Co metal film 12, an aluminum oxide (Al₂O₃) insulating layer 13, an Fe insertion 14a and a iron-nickel (NiFe) alloy (80% Ni and 20% Fe) film 15, which can be expressed as Glass/Co(100 Å)/Al₂O₃(23 Å)/Co(t Å)/NiFe(100 Å). The high TMR multilayer film structure according to the second embodiment has the same structure and manufacturing method as in the first embodiment except that the Co insertion 14 in the first embodiment is replaced by the Fe insertion 14a in the second embodiment. FIG. 4 shows a magneto-resistance curve of the multilayer film structure in the second embodiment. In the case where the aluminum oxide layer 13 thickness is 23 Å, the TMR ratio can reach 7.8%, which is much greater than the conventional TMR three-layer-film system.

From the above-mentioned preferred embodiments, one can learn that the high TMR multilayer film structure of the present invention can obtain a higher TMR ratio than the conventional three-layer-film structure due to the moderately thick (>2 Å) magnetic insertion. In particular, the TMR ratio greatly increases in the preferred insertion thickness range 8 Å to 20 Å. Thus, when the insulating layer is thick, e.g. 23 Å, the TMR ratio is still within the application range, even if the TMR ratio drops by a factor about 2 under an external voltage 0.2V.

Although the invention has been described with reference to specific embodiments, this description is not meant to be construed in a limiting sense. Various modifications of the disclosed embodiments, as well as alternative embodiments, will be apparent to persons skilled in the art. For example, the ferromagnetic film layer, the insertion or the insulating layer can be made of other materials with the same functions. It is, therefore, contemplated that the appended claims will cover all modifications that fall within the true scope of the invention.

What is claimed is:

1. A tunneling magneto-resistive (TMR) multilayer film structure with high tunneling magneto-resistance ratio, which comprises:
a first ferromagnetic film, which is made of a ferromagnetic material;
a second ferromagnetic film, which is made of a ferromagnetic material;
an insulating layer, which is composed of insulating material and formed between the first ferromagnetic film and the second ferromagnetic film; and
an insertion, which is formed between the insulating and the second ferromagnetic layer, is made of a ferromagnetic material that is different from the second ferromagnetic film, and has a thickness between 5 Å and 26 Å.

2. The structure of claim 1, wherein the ferromagnetic material is selected from the group consisting of Fe, Co and Ni.

3. The structure of claim 1, wherein the ferromagnetic material is selected from the group consisting of the alloys of Fe, Co and Ni.

4. The structure of claim 1, wherein the insulating layer is made of aluminum oxide.

5. The structure of claim 1, wherein the thickness of the insulating layer is between 20 Å and 25 Å.

6. The structure of claim 1, wherein the second ferromagnetic film and the first ferromagnetic film are made of ferromagnetic materials with the same coercive force.

7. The structure of claim 1, wherein the second ferromagnetic film and the first ferromagnetic film are made of ferromagnetic materials with different coercive forces.

8. A manufacturing method of a high tunneling magneto-resistive (TMR) multilayer film structure, which comprises the steps of:
forming a first ferromagnetic film on a substrate, the first ferromagnetic film being made of a ferromagnetic material;
forming an insulating layer on the first ferromagnetic film;
forming an insertion on the insulating layer, the insertion being made of a ferromagnetic material with a thickness ranging from 5 Å to 26 Å; and
forming a second ferromagnetic film on the insertion, the second ferromagnetic film being made of a different ferromagnetic material from that of the insertion.

9. The manufacturing method of claim 8, wherein the ferromagnetic material is selected from the group consisting of Fe, Co and Ni.

10. The manufacturing method of claim 8, wherein the ferromagnetic material is selected from the group consisting of the alloys of Fe, Co and Ni.

11. The manufacturing method of claim 8, wherein the insulating layer is made of aluminum oxide.

12. The manufacturing method of claim 8, wherein the thickness of the insulating layer is between 20 Å and 25 Å.

13. The manufacturing method of claim 8, wherein the second ferromagnetic film and the first ferromagnetic film are made of ferromagnetic materials with the same coercive force.

14. The manufacturing method of claim 8, wherein the second ferromagnetic film and the first ferromagnetic film are made of ferromagnetic materials with different coercive forces.
